(19) United States
(12) Patent Application Publication
(10) Pub. No.: US 2026/0114292 A1
(43) Pub. Date: Apr. 23, 2026

(54) CHIP PACKAGE STRUCTURE AND MANUFACTURING METHOD THEREOF

(71) Applicant: Chung W. Ho, Taipei City (TW)

(72) Inventor: Chung W. Ho, Taipei City (TW)

(21) Appl. No.: 18/923,721

(22) Filed: Oct. 23, 2024

(51) Int. Cl. H01L 23/498; H01L 21/48; H01L 21/56; H01L 23/00; H01L 23/31; H01L 23/495

(52) U.S. Cl. CPC H10W 70/04; H10W 70/40; H10W 70/411; H10W 74/117; H10W 72/07552; H10W 72/521; H10W 90/751

(57) ABSTRACT

A chip package structure includes a die pad, input/output pads, a chip, first bonding wires, a molding compound, a solder resist layer, first solder balls and second solder balls. The input/output pads are configured around the die pad. The chip is configured on the die pad. The first bonding wires are electrically connected to the chip and the input/output pads. The molding compound covers the chip, the die pad, the input/output pads and the first bonding wires, and exposes a first lower surface of the die pad and a second lower surface of each input/output pad. The solder resist layer is configured on the first lower surface of the die pad and has multiple openings exposing a portion of the die pad. The first solder balls are respectively configured in the openings of the solder resist layer, and the second solder balls are respectively configured on the input/output pads.

### BACKGROUND

### Technical Field

The disclosure relates to a package structure and a manufacturing method thereof, and in particular to a chip package structure and a manufacturing method thereof.

### Description of Related Art

In the current technology, wire bond chip scale package (CSP) mainly involves configuring the chip on an organic substrate configured with fan-out circuits and electrically connecting the chip to the organic substrate through wire bonding. However, the organic substrate configured with fan-out circuits not only requires complex manufacturing steps but is also relatively expensive, thereby increasing the manufacturing cost of the chip package structure. Therefore, effectively reducing the manufacturing steps and costs of wire bond CSP has become one of the issues urgently needing a solution.

### SUMMARY

The disclosure provides a chip package structure and a manufacturing method thereof, which offers advantages of simplicity in the manufacturing process and low cost.

A chip package structure of the disclosure includes a die pad, multiple input/output pads, a chip, multiple first bonding wires, a molding compound, a solder resist layer, multiple first solder balls, and multiple second solder balls. The input/output pads are configured around the die pad. The chip is configured on the die pad. The first bonding wires electrically connect the chip to the input/output pads. The molding compound covers the chip, the die pad, the input/output pads, and the first bonding wires, and exposes a first lower surface of the die pad and a second lower surface of each of the input/output pads. The first bottom surface of the molding compound is aligned with the second lower surface of each of the input/output pads. The solder resist layer is configured on the first lower surface of the die pad. The solder resist layer has multiple openings, which expose a portion of the die pad. The second bottom surface of the solder resist layer is aligned with the first bottom surface of the molding compound. The first solder balls are respectively configured in the openings of the solder resist layer and electrically connected to the die pad exposed by the openings. The second solder balls are respectively configured on the input/output pads and electrically connected to the input/output pads.

In an embodiment of the disclosure, the chip package structure further includes at least one bridge pad and at least one second bonding wire. The bridge pad is configured between the input/output pads. The second bonding wire is electrically connected to the at least one bridge pad and the input/output pads.

In an embodiment of the disclosure, when the distance between any adjacent two of the input/output pads is 0.5 millimeters, the number of bridge pads is equal to the number of input/output pads.

In an embodiment of the disclosure, when the distance between any adjacent two of the input/output pads is 0.65 millimeters, the number of bridge pads is equal to three times the number of input/output pads.

In an embodiment of the disclosure, the size of the bridge pad is smaller than the size of each of the input/output pads.

A manufacturing method of the chip package structure in the disclosure includes the following steps. A carrier is provided. The carrier includes a substrate, a stainless steel layer, and a metal layer. The stainless steel layer is formed on the substrate and conformally covers the substrate. The metal layer is formed on the stainless steel layer and conformally covers the stainless steel layer. Using the metal layer as a plating seed layer, a patterned conductive layer is formed on the metal layer. The substrate and the stainless steel layer are removed, exposing the metal layer. A solder resist layer is formed on the metal layer, with the solder resist layer having multiple openings that expose a portion of the metal layer. A portion of the metal layer is removed, such that the remaining portion of the metal layer and a part of the patterned conductive layer define the die pad, while another part of the patterned conductive layer defines the plurality of input/output pads. A chip is configured on the die pad. Multiple first bonding wires are formed to electrically connect the chip to the plurality of input/output pads. A molding compound is formed to cover the chip, the die pad, the plurality of input/output pads, and the first bonding wires, and to expose a first lower surface of the die pad and a second lower surface of each of the input/output pads. The first bottom surface of the molding compound is aligned with the second lower surface of each of the input/output pads, and the second bottom surface of the solder resist layer is aligned with the first bottom surface of the molding compound. Multiple first solder balls and multiple second solder balls are formed. The first solder balls are respectively configured in the openings of the solder resist layer and electrically connected to the die pad exposed by the openings. The second solder balls are respectively configured on the input/output pads and electrically connected to the input/output pads.

In an embodiment of the disclosure, the manufacturing method of the chip package structure further includes, when removing a portion of the metal layer, defining at least one bridge pad with the remaining portion of the metal layer and a part of the patterned conductive layer, with the at least one bridge pad configured between the input/output pads. At least one second bonding wire is formed to electrically connect the at least one bridge pad to the input/output pads.

Based on the above, in the chip package structure of the disclosure, the input/output pads are configured around the die pad, with the chip configured on the die pad and electrically connected to the input/output pads through the first bonding wires. In other words, the disclosure does not adopt the organic substrate configured with fan-out circuits used in the prior art. Therefore, the chip package structure and the manufacturing method thereof in the disclosure can offer the advantages of a simple process and low cost.

### BRIEF DESCRIPTION OF THE DRAWINGS

FIG. 1 is a cross-sectional schematic diagram of a chip package structure according to an embodiment of the disclosure.

FIGS. 2A to 2E are cross-sectional schematic diagrams of a manufacturing method for a chip package structure according to an embodiment of the disclosure.

FIG. 3 is a top view schematic diagram of input/output pads and bridge pads according to an embodiment of the disclosure.

FIG. 4 is a top view schematic diagram of input/output pads and bridge pads according to another embodiment of the disclosure.

### DESCRIPTION OF THE EMBODIMENTS

The embodiments of the disclosure can be understood in conjunction with the figures, which are considered part of the disclosure. It should be understood that the figures of the disclosure are not drawn to scale and, in fact, the sizes of the elements may be arbitrarily enlarged or reduced to clearly depict the features of the disclosure.

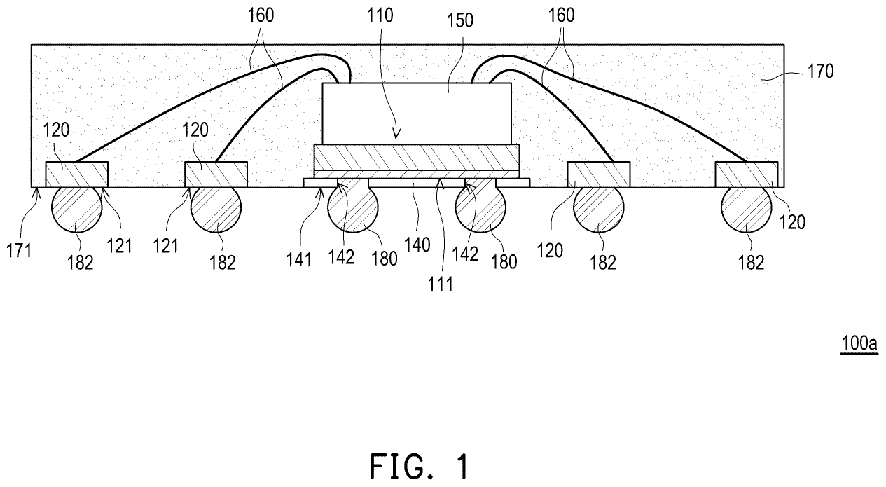

FIG. 1 is a cross-sectional schematic diagram of a chip package structure according to an embodiment of the disclosure. Referring to FIG. 1, in this embodiment, a chip package structure 100a includes a die pad 110, multiple input/output pads 120, a chip 150, multiple first bonding wires 160, a molding compound 170, a solder resist layer 140, multiple first solder balls 180, and multiple second solder balls 182. The input/output pads 120 are configured around the die pad 110. The chip 150 is configured on the die pad 110. The first bonding wires 160 electrically connect the chip 150 to the input/output pads 120. The molding compound 170 covers the chip 150, the die pad 110, the input/output pads 120, and the first bonding wires 160, while exposing a first lower surface 111 of the die pad 110 and a second lower surface 121 of each of the input/output pads 120.

As shown in FIG. 1, a first bottom surface 171 of the molding compound 170 is substantially aligned with the second lower surface 121 of each of the input/output pads 120. The molding compound 170 completely covers the surrounding surface of the input/output pads 120, meaning that the edge of the molding compound 170 extends a distance beyond the edge of the input/output pads 120, presenting a non-aligned condition. In an embodiment, the size of the die pad 110 may be larger than the size of the input/output pads 120, and the die pad 110 may be slightly thicker than the input/output pads 120.

Furthermore, in this embodiment, the chip 150 is configured on the die pad 110 and bonded to the input/output pads 120 by wire bonding. In other words, this embodiment does not use an organic substrate configured with fan-out circuits as in the prior art, nor does it use a lead frame, thereby effectively reducing costs. In an embodiment, the material of the die pad 110 and the material of the input/output pads 120 may both be, for example, copper, but are not limited thereto. In an embodiment, the first bonding wires 160 are bonded to the input/output pads 120 at a distance less than or equal to 4 millimeters from the edge of the die pad 110.

Moreover, in this embodiment, the solder resist layer 140 is configured on the first lower surface 111 of the die pad 110. As shown in FIG. 1, the solder resist layer 140 has multiple openings 142, which expose portions of the die pad 110. Here, a second bottom surface 141 of the solder resist layer 140 is substantially aligned with the first bottom surface 171 of the molding compound 170.

Additionally, in this embodiment, the first solder balls 180 are respectively configured in the openings 142 of the solder resist layer 140 and electrically connected to the die pad 110 exposed by the openings 142. The second solder balls 182 are respectively configured on the input/output pads 120 and electrically connected to the input/output pads 120.

In short, this embodiment uses the die pad 110 and input/output pads 120 to replace the organic substrate configured with fan-out circuits in the prior art. Therefore, the chip package structure 100a and the manufacturing method thereof in this embodiment can offer the advantages of a simple process and low cost.

It should be noted that the following embodiments continue to use the same reference numbers and some content from the previous embodiments. The same reference numbers are used to represent the same or similar elements, and the descriptions of the same technical content are omitted. References may be made to the previous embodiments for the omitted descriptions, which will not be repeated in the following embodiments.

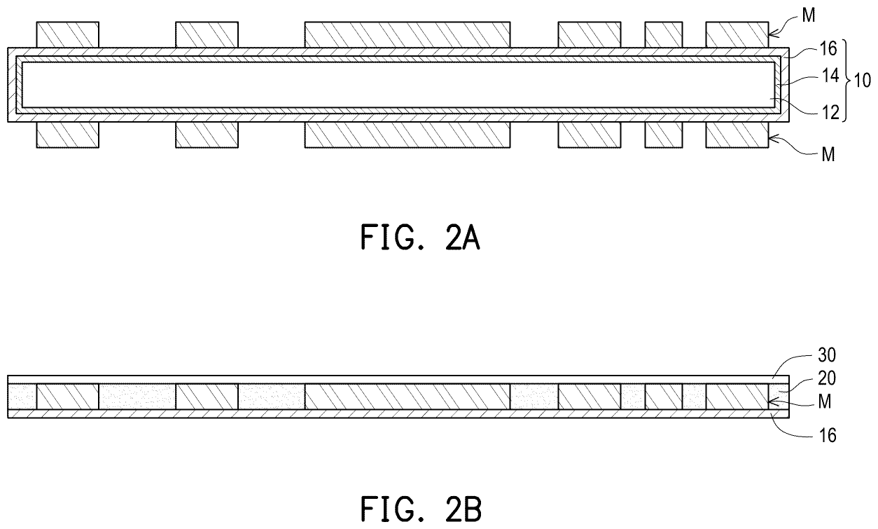

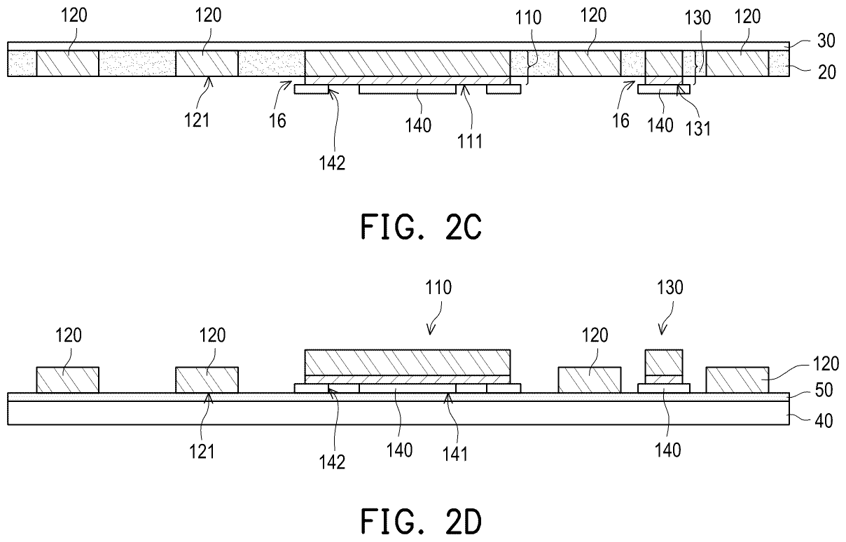

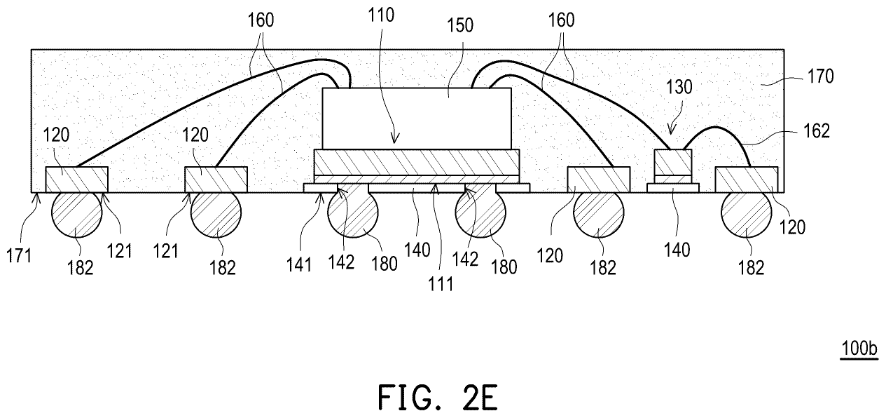

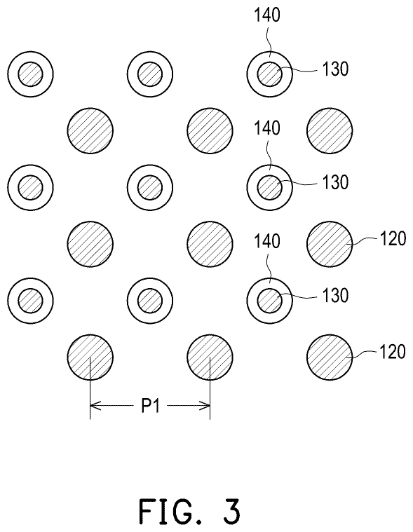

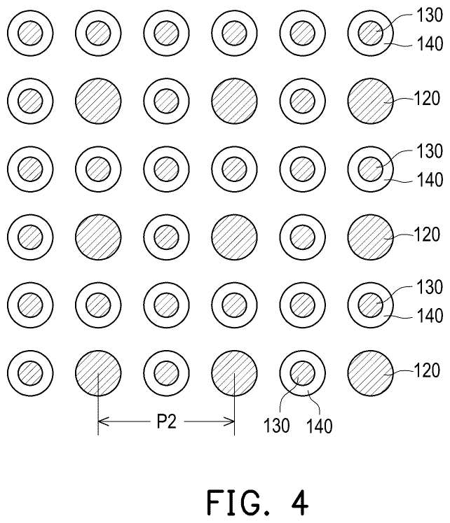

FIGS. 2A to 2E are cross-sectional schematic diagrams of the manufacturing method for a chip package structure according to an embodiment of the disclosure. FIG. 3 is a top view schematic diagram of input/output pads and bridge pads according to an embodiment of the disclosure. FIG. 4 is a top view schematic diagram of input/output pads and bridge pads according to another embodiment of the disclosure.

Referring to both FIGS. 1 and 2E at the same time, a chip package structure 100b in this embodiment is similar to the previously described chip package structure 100a, with the main difference being: in this embodiment, the chip package structure 100b further includes at least one bridge pad (schematically shown as a bridge pad 130) and at least one second bonding wire (schematically shown as a second bonding wire 162). The bridge pad 130 is configured between the input/output pads 120. The first bonding wire 160 is electrically connected to the chip 150 and the bridge pad 130, while the second bonding wire 162 is electrically connected to the bridge pad 130 and the input/output pads 120. In an embodiment, the second bonding wire 162 is connected to a bridge pad 130 and an input/output pad 120 at a distance greater than 4 millimeters or 8 millimeters from the edge of the die pad 110. In an embodiment, the size of the bridge pad 130 is smaller than the size of each of the input/output pads 120. In an embodiment, the diameter of the bridge pad 130 is, for example, 0.125 millimeters, while the diameter of each of the input/output pads 120 is, for example, 0.25 millimeters, but is not limited thereto.

In this embodiment, the chip 150 is electrically connected to the input/output pads 120 by means of wire bonding. However, wire bonding has a length limitation, so the layout of the input/output pads 120 is usually not too far from the die pad 110, which limits the number of input/output pads 120. Since this embodiment includes the bridge pad 130, which can serve as a relay station or stepping stone, the issue of excessive wire bonding length can be avoided. Therefore, additional input/output pads 120 can be arranged on the periphery of the bridge pad 130 (away from the die pad 110). The chip 150 is first electrically connected to the bridge pad 130 by the first bonding wire 160, and then the bridge pad 130 is electrically connected to the input/output pads 120 located on the periphery of the bridge pad 130 (away from the die pad 110) by the second bonding wire 162. In this way, the number of input/output pads 120 can be effectively increased.

Referring to FIG. 3, in an embodiment, when the distance P1 between any two adjacent input/output pads 120 is 0.5 millimeters, the number of bridge pads 130 can be equal to the number of input/output pads 120. Specifically, the number of bridge pads 130 is 9, and the number of input/output pads 120 is also 9. In an embodiment, when the distance P1 between any two adjacent input/output pads 120 is 0.5 millimeters, if there is no design for the bridge pad 130, the size of the chip package structure is 12 millimeters by 12 millimeters. In contrast, with the design of one bridge pad 130, the size of the chip package structure can be increased to 15 millimeters by 15 millimeters, thereby enhancing the applicability of the chip package structure.

Referring to FIG. 4, in an embodiment, when the distance P2 between any two adjacent input/output pads 120 is 0.65 millimeters, the number of bridge pads 130 is equal to three times the number of input/output pads 120. Specifically, the number of bridge pads 130 is 27, and the number of input/output pads 120 is 9. In an embodiment, when the distance P2 between any two adjacent input/output pads 120 is 0.65 millimeters, if there is no design for the bridge pad 130, the size of the chip package structure is 20 millimeters by 20 millimeters. In contrast, with the design of three bridge pads 130, the size of the chip package structure can be increased to 30 millimeters by 30 millimeters, thereby enhancing the applicability of the chip package structure.

In terms of the process, please first refer to FIG. 2A. Regarding the manufacturing method for the chip package structure of this embodiment, first, a carrier 10 is provided. The carrier includes a substrate 12, a stainless steel layer 14, and a metal layer 16. The stainless steel layer 14 is formed on the substrate 12 and conformally covers the substrate 12. The metal layer 16 is formed on the stainless steel layer 14 and conformally covers the stainless steel layer 14. Here, the substrate 12 can be, for example, a core substrate, which consists of a sheet-like fiberglass resin base and copper foil disposed on both opposing sides of the sheet-like fiberglass resin base. It can be considered a type of rigid board, but is not limited thereto.

Next, referring again to FIG. 2A, a patterned photoresist layer (not shown) is disposed on the metal layer 16, and using the metal layer 16 as a plating seed layer, a patterned conductive layer M is formed on the metal layer 16, wherein the patterned conductive layer M exposes portions of the metal layer 16. In an embodiment, the material of the patterned conductive layer M is copper, but is not limited thereto. Afterward, the patterned photoresist layer is removed, exposing portions of the metal layer 16.

Next, referring to FIG. 2B, a tape 30 and an ultraviolet (UV) adhesive 20 applied on the tape 30 are provided on the patterned conductive layer M, where the UV adhesive 20 covers the exposed portions of the metal layer 16 on the patterned conductive layer M, and the tape 30 covers the UV adhesive 20 and the patterned conductive layer M. Through the adhesive forces of the tape 30 and the UV adhesive 20, the metal layer 16 is separated from the stainless steel layer 14, thus allowing for the removal of the substrate 12 and the stainless steel layer 14 on it. At this point, the patterned conductive layer M is sandwiched between the tape 30 and the metal layer 16.

Next, referring to both FIGS. 2B and 2C, a solder resist layer 140 is formed on the metal layer 16, where the solder resist layer 140 has multiple openings 142 that expose portions of the metal layer 16. Immediately after, part of the metal layer 16 is removed through an etching process, leaving the remaining metal layer 16 and a portion of the patterned conductive layer M to define the die pad 110 and the bridge pads 130. Another portion of the patterned conductive layer M defines the input/output pads 120. In an embodiment, the size of the bridge pads 130 is smaller than that of each of the input/output pads 120, while the size of the die pad 110 is larger than that of each of the input/output pads 120.

Referring again to FIG. 2C, as shown, the solder resist layer 140 is formed on the first lower surface 111 of the die pad 110 and a bottom surface 131 of the bridge pads 130. In other words, the solder resist layer 140 is not formed on the second lower surface 121 of the input/output pads 120. In an embodiment, the projected area of the die pad 110 onto the solder resist layer 140 can be less than or equal to the area of the solder resist layer 140. In an embodiment, the projected area of the bridge pads 130 onto the solder resist layer 140 can be less than or equal to the area of the solder resist layer 140.

Next, referring to both FIGS. 2C and 2D, a substrate 40 and an adhesive layer 50 configured on the substrate 40 are provided under the solder resist layer 140 shown in FIG. 2C, so that the solder resist layer 140 and the input/output pads 120 are temporarily fixed directly onto the adhesive layer 50 of the substrate 40. Immediately after, by exposing the UV adhesive 20 to ultraviolet light, the UV adhesive 20 loses adhesive properties, and the tape 30 is removed through peeling. At this point, the second lower surface 121 of the input/output pads 120 and the second bottom surface 141 of the solder resist layer 140 are coplanar and directly adhered to the adhesive layer 50.

Next, referring to FIG. 2E, the chip 150 is configured on the die pad 110, where the size of the die pad 110 is larger than the size of the chip 150. Then, multiple first bonding wires 160 are formed to electrically connect the chip 150 to the input/output pads 120, and a second bonding wire 162 is formed to electrically connect the bridge pad 130 to the input/output pads 120. Immediately after, a molding compound 170 is formed to cover the chip 150, the die pad 110, the input/output pads 120, the first bonding wires 160, and the second bonding wire 162, while exposing the second lower surface 121 of each input/output pad 120 and the second bottom surface 141 of the solder resist layer 140. At this point, the first bottom surface 171 of the molding compound 170 is aligned with the second lower surface 121 of the input/output pads 120 and the second bottom surface 141 of the solder resist layer 140. Finally, multiple first solder balls 180 and multiple second solder balls 182 are formed, with the first solder balls 180 being formed in the openings 142 of the solder resist layer 140 and electrically connected to the die pad 110 exposed by the openings 142. The second solder balls 182 are respectively formed on the input/output pads 120 and electrically connected to the input/output pads 120. At this point, the manufacturing of the chip package structure 100b is complete.

In summary, in the chip package structure of the disclosure, the input/output pads are arranged around the die pad, where the chip is configured on the die pad and electrically connected to the input/output pads through the first bonding wires. In other words, the disclosure does not use an organic substrate configured with fan-out circuits as in the prior art. Therefore, the chip package structure and the manufacturing method thereof in the disclosure can offer the advantages of a simple process and low cost.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. A chip package structure, comprising:
a die pad;
a plurality of input/output pads, configured around the die pad;
a chip, configured on the die pad;
a plurality of first bonding wires, electrically connected to the chip and the plurality of input/output pads;
a molding compound, covering the chip, the die pad, the plurality of input/output pads, and the plurality of first bonding wires, and exposing a first lower surface of the die pad and a second lower surface of each of the plurality of input/output pads, wherein a first bottom surface of the molding compound is aligned with the second lower surface of each of the plurality of input/output pads;
a solder resist layer, configured on the first lower surface of the die pad, wherein the solder resist layer has a plurality of openings, and the plurality of openings expose a portion of the die pad, and a second bottom surface of the solder resist layer is aligned with the first bottom surface of the molding compound;
a plurality of first solder balls, respectively configured in the plurality of openings of the solder resist layer and electrically connected to the die pad exposed by the plurality of openings; and
a plurality of second solder balls, respectively configured on the plurality of input/output pads and electrically connected to the plurality of input/output pads.

2. The chip package structure according to claim 1, further comprising:
at least one bridge pad, configured between the plurality of input/output pads; and
at least one second bonding wire, electrically connected to the at least one bridge pad and the plurality of input/output pads.

3. The chip package structure according to claim 2, wherein when a distance between any adjacent two of the plurality of input/output pads is 0.5 millimeters, a number of the at least one bridge pad is equal to a number of the plurality of input/output pads.

4. The chip package structure according to claim 2, wherein when a distance between any adjacent two of the plurality of input/output pads is 0.65 millimeters, a number of the at least one bridge pad is equal to three times a number of the plurality of input/output pads.

5. The chip package structure according to claim 2, wherein a size of the at least one bridge pad is smaller than a size of each of the plurality of input/output pads.

6. A manufacturing method of a chip package structure, comprising:
providing a carrier, the carrier comprising a substrate, a stainless steel layer, and a metal layer, wherein the stainless steel layer is formed on the substrate and conformally covers the substrate, and the metal layer is formed on the stainless steel layer and conformally covers the stainless steel layer;
using the metal layer as a plating seed layer to form a patterned conductive layer on the metal layer;
removing the substrate and the stainless steel layer to expose the metal layer;
forming a solder resist layer on the metal layer, wherein the solder resist layer have a plurality of openings, and the plurality of openings expose a portion of the metal layer;
removing the portion of the metal layer, wherein a remaining portion of the metal layer and a portion of the patterned conductive layer define the die pad, and another portion of the patterned conductive layer defines the plurality of input/output pads;
configuring a chip on the die pad;
forming a plurality of first bonding wires such that the chip and the plurality of input/output pads are electrically connected;
forming a molding compound to cover the chip, the die pad, the plurality of input/output pads, and the plurality of first bonding wires, and exposing a first lower surface of the die pad and a second lower surface of each of the plurality of input/output pads, wherein a first bottom surface of the molding compound is aligned with the second lower surface of each of the plurality of input/output pads, and a second bottom surface of the solder resist layer is aligned with the first bottom surface of the molding compound; and
forming a plurality of first solder balls and a plurality of second solder balls, wherein the plurality of first solder balls are respectively configured in the plurality of openings of the solder resist layer and electrically connected to the die pad exposed by the plurality of openings, and the plurality of second solder balls are respectively configured on the plurality of input/output pads and electrically connected to the plurality of input/output pads.

7. The manufacturing method of the chip package structure according to claim 6, further comprising:
when removing the portion of the metal layer, the remaining portion of the metal layer and the portion of the patterned conductive layer also define at least one bridge pad, and the at least one bridge pad is configured between the plurality of input/output pads; and
forming at least one second bonding wire such that the at least one bridge pad and the plurality of input/output pads are electrically connected.

8. The manufacturing method of the chip package structure according to claim 7, wherein when a distance between any adjacent two of the plurality of input/output pads is 0.5 millimeters, a number of the at least one bridge pad is equal to a number of the plurality of input/output pads.

9. The manufacturing method of the chip package structure according to claim 7, wherein when a distance between any adjacent two of the plurality of input/output pads is 0.65 millimeters, a number of the at least one bridge pad is equal to three times a number of the plurality of input/output pads.

10. The manufacturing method of the chip package structure according to claim 7, wherein a size of the at least one bridge pad is smaller than a size of each of the plurality of input/output pads.
